(19) United States
(12) Patent Application Publication
(10) Pub. No.: US 2022/0217854 A1
(43) Pub. Date: Jul. 7, 2022

(54) SEALED AND UNSEALED ELECTRONIC ASSEMBLIES USING COMMON DESIGN

(71) Applicant: Neapco Intellectual Property Holdings, LLC, Farmington Hills, MI (US)

(72) Inventors: Kiran Soni, Rochester Hills, MI (US); John Ogger, Farmington Hills, MI (US); Alia Comai, Northville, MI (US); Phil Kennedy, Farmington Hills, MI (US); Jayadevaswamy Matada Basavarajaiah, Bangalore (IN)

(21) Appl. No.: 17/570,017

(22) Filed: Jan. 6, 2022

Related U.S. Application Data
(60) Provisional application No. 63/134,654, filed on Jan. 7, 2021.

(51) Int. Cl. H05K 5/00; H05K 7/20; H05K 5/03

(52) U.S. Cl. CPC H05K 5/0069; H05K 7/2039; H01R 13/521; H05K 5/03; H05K 5/0008

(57) ABSTRACT

An electronic assembly is provided. The electronic assembly includes a housing and an electrical connector that is one of an unsealed connector and a sealed connector. The electronic assembly also includes a printed circuit board disposed at least partially in the housing. The printed circuit board is configured to accept the one of the unsealed connector and the sealed connector.

### CROSS REFERENCE TO RELATED APPLICATIONS

This utility application claims the benefit of U.S. Provisional Application No. 63/134,654 filed Jan. 7, 2021. The entire disclosure of the above application is incorporated herein by reference.

### FIELD

The present disclosure relates generally to electronic assemblies. More particularly, the present disclosure is directed to sealed and unsealed electronic assemblies using a common design.

### BACKGROUND

This section provides background information related to the present disclosure which is not necessarily prior art.

Electronic assemblies used on vehicles may be installed or packaged in various locations of the vehicle. Some locations, such as the exterior of the vehicle, may require that the electronic assemblies are sealed to prevent intrusion of moisture and or contaminants. In contrast, the electronic assemblies packaged in interior locations do not require a sealed arrangement. In fact, for interior locations, it may even be preferable that the electronic assembly is not sealed in order to provide better ventilation and/or cooling. Furthermore, different wiring connectors (e.g., sealed vs. unsealed) may be needed depending on the packaging location. As a result, the prior art electronic assemblies are designed for their intended use—one design for use in an exterior environment and a separate design for use in an interior environment. However, the requirement to manufacture and store multiple assembly designs results in increased cost and complexity. Accordingly, there remains a continuing need for an electronic assembly with more universal parts and which can be used in both exterior and interior applications.

### SUMMARY

This section provides a general summary of the present disclosure and is not a comprehensive disclosure of its full scope or all of its features, aspects and objectives.

It is an aspect of the present disclosure to provide an electronic assembly including a housing and an electrical connector that is one of an unsealed connector and a sealed connector. The electronic assembly also includes a printed circuit board disposed at least partially in the housing. The printed circuit board is configured to accept either one of the unsealed connector and the sealed connector. Consequently, the electronic assembly can be used in both exterior and interior applications.

It is another aspect of the present disclosure to provide an electronic assembly including a housing having a top portion. The housing also includes a bottom portion configured to attach to the top portion and define a compartment therebetween. A printed circuit board is disposed at least partially in the housing. An electrical connector is attached to the printed circuit board and is one of an unsealed connector and a sealed connector. At least one of the top portion and the bottom portion is configured to receive either the unsealed connector in an unsealed fashion or the sealed connector in a sealed fashion. As a result, the electronic assembly can be used in both exterior and interior applications.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is an exploded view of an electronic assembly including a unsealed connector according to aspects of the disclosure; and

FIG. 2 is an exploded view of the electronic assembly including a sealed connector and additional components for sealing the electronic assembly according to aspects of the disclosure.

### DETAILED DESCRIPTION

In the following description, details are set forth to provide an understanding of the present disclosure. In some instances, certain circuits, structures and techniques have not been described or shown in detail in order not to obscure the disclosure.

In general, example embodiments of electronic assemblies constructed in accordance with the teachings of the present disclosure will now be disclosed. The example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are described in detail.

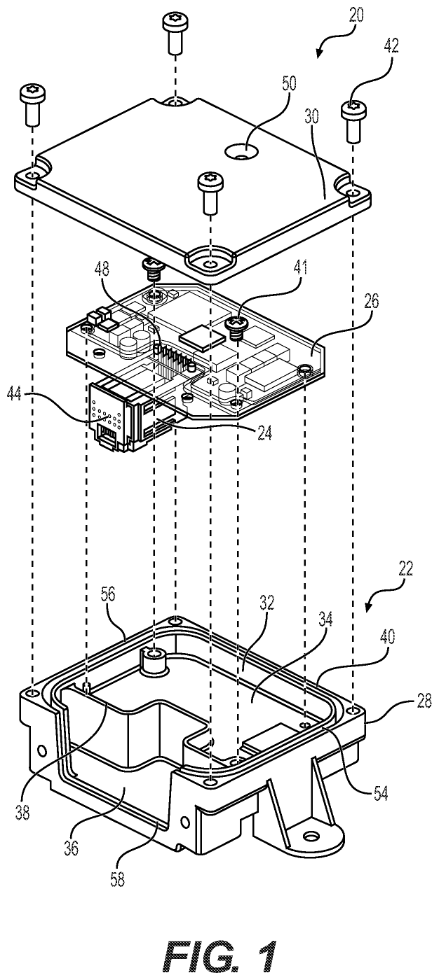

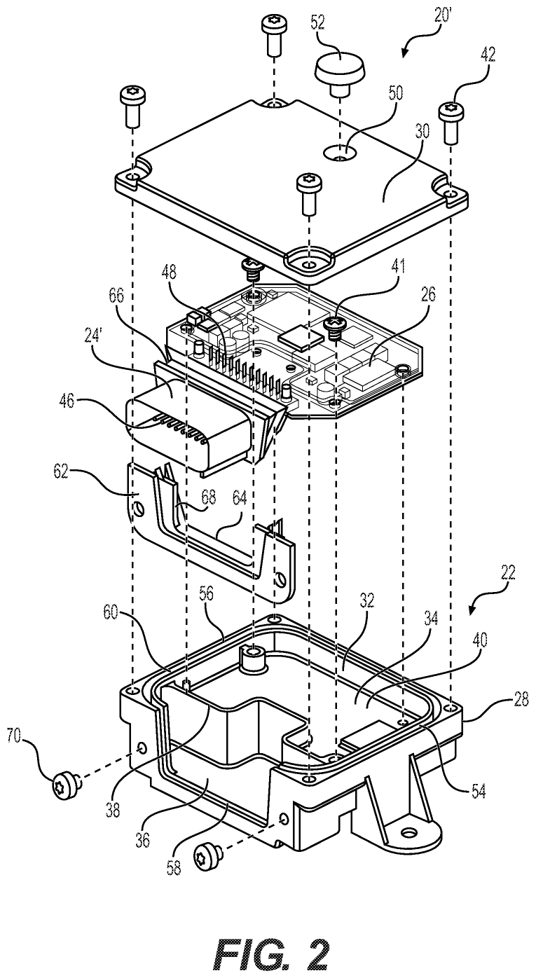

Now referring to FIGS. 1 and 2, an electronic assembly 20, 20′ is provided. The electronic assembly 20, 20′ includes a housing 22. The electronic assembly 20, 20′ also includes an electrical connector 24, 24′ that is one of an unsealed connector 24 (FIG. 1) or a sealed connector 24′ (FIG. 2). In addition, the electronic assembly 20, 20′ includes a printed circuit board 26 disposed at least partially in the housing 22. The printed circuit board 26 is configured to accept the one of the unsealed connector 24 and the sealed connector 24′.

The housing 22 includes a top portion 28 and a bottom portion 30 configured to attach to the top portion 28 over the printed circuit board 26. The top portion 28 and the bottom portion 30 define a compartment 32 therebetween. In addition, at least one of the top portion 28 and the bottom portion 30 is configured to receive (i.e., house and secure) the one of the unsealed connector 24 in an unsealed fashion and the sealed connector 24′ in a sealed fashion. So, the same housing 22 may be used regardless of which electrical connector 24, 24′ is used, as either is accommodated.

The compartment 32 is divided into a board portion 34 and a connector portion 36 by a partition 38 formed in the top portion 28 of the housing 22. According to an aspect, the top portion 28 includes or acts as a heatsink 40 configured to be adjacent the printed circuit board 26 (e.g., in the board portion 34 of the compartment 32) and remove heat from the printed circuit board 26. A plurality of board fasteners 41 secure the printed circuit board 26 to the top portion 28 of the housing 22. A plurality of housing fasteners 42 (e.g., screws) attach the top portion 28 to the bottom portion 30. Nevertheless, it should be understood that such fasteners 41, 42 may be omitted if, for example, the top portion 28 and the bottom portion 30 are configured to snap together while securing the printed circuit board 26.

The unsealed connector 24 includes a plurality of unsealed terminals 44 (FIG. 1) and the sealed connector 24′ includes a plurality of sealed terminals 46 (FIG. 2). In order for the printed circuit board 26 to accept the one of the unsealed connector 24 and the sealed connector 24′, the printed circuit board 26 includes electrical traces 48 (e.g., electrically conductive or copper or metal traces) disposed thereon for conducting electrical signals and/or power (e.g., electrical power for powering the electronic assembly 20, 20′) to and from the electrical connector 24, 24′. The electrical traces 48 are configured to connect to one of the plurality of unsealed terminals 44 and the plurality of sealed terminals 46 depending on whether the electrical connector 24, 24′ is the unsealed connector 24 or the sealed connector 24′. In other words, the tracing 48 of the printed circuit board 26 is laid out to accept either (i.e., both, one at a time) the sealed connector 24′ or the unsealed connector 24. The housing 22 also defines a breather opening 50 (e.g., in the bottom portion 30) for equalizing pressure within the housing 22.

Referring specifically to FIG. 2, the electronic assembly 20, 20′ further includes a breather valve 52 disposed in the breather opening 50 for equalizing the pressure within the housing 22, while preventing the intrusion of moisture or contaminants. The top portion 28 of the housing 22 defines a gasket notch 54 around at least a portion of a periphery 56 of the top portion 28. The top portion 28 of the housing 22 also defines a cover plate recess 58 extending into the top portion 28 (e.g., open to the connector portion 36 of the compartment 32). The electronic assembly 20, 20′ includes a gasket 60 (e.g., a form-in-place (FIP) gasket) disposed in the gasket notch 54 for sealing the top portion 28 of the housing 22 to the bottom portion 30 of the housing 22.

The electronic assembly 20, 20′ also includes a connector cover plate 62 disposed in the cover plate recess 58 and defining a connector recess 64 extending into the connector cover plate 62. The connector recess 64 is configured to receive the sealed connector 24′. More specifically, the sealed connector 24′ includes a connector channel 66 extending around the sealed connector 24′, the connector channel 66 engages a plate rim 68 of the connector cover plate 62 when the sealed connector 24′ is disposed in the connector recess 64 of the connector cover plate 62. The electronic assembly 20, 20′ additionally includes a plurality of connector cover plate fasteners 70 for attaching the connector cover plate 62 to the top portion 28 of the housing 22.

To achieve economies of scale, the electronic assembly 20, 20′ may be used across vehicle lines, for example. More specifically, when no sealing is required, electronic assembly 20 may be used; however, if sealing is required, electronic assembly 20′ may be used. Because the traces 48 of the printed circuit board 26 are laid out to accept either the sealed connector 24′ or the unsealed connector 24, the printed circuit board 26, top portion 28 and bottom portion 30 of the housing 22, board fasteners 41, housing fasteners 42, can advantageously be common between the electronic assemblies 20, 20′. Additionally, the cover plate recess 58 extending into the top portion 28 is large enough for either the sealed connector 24′ or the unsealed connector 24 and, thus, when sealing is required, the connector cover plate 62 may be utilized in addition to the sealed connector 24′ and breather valve 52 (i.e., these parts are added to the common or universal design of the electronic assembly 20 to result in electronic assembly 20′).

Clearly, changes may be made to what is described and illustrated herein without, however, departing from the scope defined in the accompanying claims. The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “bottom,” “above,” “upper,” “top,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

What is claimed is:

1. An electronic assembly comprising:
a housing;
an electrical connector being one of an unsealed connector and a sealed connector; and
a printed circuit board disposed at least partially in the housing and configured to accept the one of the unsealed connector and the sealed connector.

2. The electronic assembly as set forth in claim 1, wherein the unsealed connector includes a plurality of unsealed terminals and the sealed connector includes a plurality of sealed terminals;
the printed circuit board includes electrical traces disposed thereon for conducting electrical signals and power to and from the electrical connector; and
the electrical traces are configured to connect to one of the plurality of unsealed terminals and the plurality of sealed terminals depending on whether the electrical connector is the unsealed connector or the sealed connector.

3. The electronic assembly as set forth in claim 1, wherein the housing defines a breather opening and the electronic assembly further includes a breather valve disposed in the breather opening for equalizing pressure within the housing while preventing intrusion of moisture or contaminants.

4. The electronic assembly as set forth in claim 1, wherein the housing defines a breather opening for equalizing pressure within the housing.

5. The electronic assembly as set forth in claim 1, wherein the housing includes:
a top portion; and
a bottom portion configured to attach to the top portion over the printed circuit board, the top portion and the bottom portion defining a compartment therebetween.

6. The electronic assembly as set forth in claim 5, wherein the top portion includes a heatsink configured to be adjacent the printed circuit board and remove heat therefrom.

7. The electronic assembly as set forth in claim 5, wherein the housing further includes a plurality of housing fasteners for attaching the top portion to the bottom portion.

8. The electronic assembly as set forth in claim 5, wherein:
the top portion defines a gasket notch around at least a portion of a periphery of the top portion and a cover plate recess extending into the top portion; and
the electronic assembly further includes a gasket disposed in the gasket notch for sealing the top portion of the housing to the bottom portion of the housing.

9. The electronic assembly as set forth in claim 8, further including:
a connector cover plate disposed in the cover plate recess and defining a connector recess extending into the connector cover plate and configured to receive the sealed connector, and
a plurality of connector cover plate fasteners for attaching the connector cover plate to the top portion of the housing.

10. The electronic assembly as set forth in claim 9, wherein the sealed connector includes a connector channel extending around the sealed connector, the connector channel engaging a plate rim of the connector cover plate when the sealed connector is disposed in the connector recess of the connector cover plate.

11. An electronic assembly comprising:
a housing including a top portion;
the housing including a bottom portion configured to attach to the top portion and define a compartment therebetween;
a printed circuit board disposed at least partially in the housing;
an electrical connector attached to the printed circuit board and being one of an unsealed connector and a sealed connector; and
at least one of the top portion and the bottom portion being configured to receive the one of the unsealed connector in an unsealed fashion and the sealed connector in a sealed fashion.

12. The electronic assembly as set forth in claim 11, wherein the unsealed connector includes a plurality of unsealed terminals and the sealed connector includes a plurality of sealed terminals;
the printed circuit board includes electrical traces disposed thereon for conducting electrical signals and power to and from the electrical connector; and
the electrical traces are configured to connect to one of the plurality of unsealed terminals and the plurality of sealed terminals depending on whether the electrical connector is the unsealed connector or the sealed connector.

13. The electronic assembly as set forth in claim 11, wherein the housing defines a breather opening and the electronic assembly further includes a breather valve disposed in the breather opening for equalizing pressure within the housing while preventing intrusion of moisture or contaminants.

14. The electronic assembly as set forth in claim 11, wherein the housing defines a breather opening for equalizing pressure within the housing.

15. The electronic assembly as set forth in claim 11, wherein the housing includes:
a top portion; and
a bottom portion configured to attach to the top portion over the printed circuit board, the top portion and the bottom portion defining a compartment therebetween.

16. The electronic assembly as set forth in claim 15, wherein the top portion includes a heatsink configured to be adjacent the printed circuit board and remove heat therefrom.

17. The electronic assembly as set forth in claim 15, wherein the housing further includes a plurality of housing fasteners for attaching the top portion to the bottom portion.

18. The electronic assembly as set forth in claim 15, wherein:
the top portion defines a gasket notch around at least a portion of a periphery of the top portion and a cover plate recess extending into the top portion; and
the electronic assembly further includes a gasket disposed in the gasket notch for sealing the top portion of the housing to the bottom portion of the housing.

19. The electronic assembly as set forth in claim 18, further including:
a connector cover plate disposed in the cover plate recess and defining a connector recess extending into the connector cover plate and configured to receive the sealed connector, and
a plurality of connector cover plate fasteners for attaching the connector cover plate to the top portion of the housing.

20. The electronic assembly as set forth in claim 19, wherein the sealed connector includes a connector channel extending around the sealed connector, the connector channel engaging a plate rim of the connector cover plate when the sealed connector is disposed in the connector recess of the connector cover plate.
